(19) United States
(12) Patent Application Publication
(10) Pub. No.: US 2016/0049478 A1
(43) Pub. Date: Feb. 18, 2016

(54) SEMICONDUCTOR DEVICE AND METHOD FOR FABRICATING THE SAME

(71) Applicant: Samsung Electronics Co., Ltd., Suwon-si (KR)

(72) Inventors: Moon-Kyun Song, Anyang-si (KR); Weon-Hong Kim, Suwon-si (KR); Soo-Jung Choi, Yangju-si (KR); Yoon-Tae Hwang, Seoul (KR)

(21) Appl. No.: 14/678,331

(22) Filed: Apr. 3, 2015

(30) Foreign Application Priority Data
Aug. 18, 2014 (KR) 10-2014-0106987

(51) Int. Cl. H01L 29/40; H01L 29/49; H01L 29/51

(52) U.S. Cl. CPC H01L 29/401; H01L 29/517; H01L 29/4966

(57) ABSTRACT

A method for fabricating a semiconductor device comprises forming a gate insulation layer on a substrate including a first region and a second region, forming a first gate conductive layer and a capping layer on the first region and the second region and heat-treating the substrate, removing the capping layer from the first region and the second region, forming a second gate conductive layer on the first region and the second region, nitriding the second gate conductive layer, and forming a third gate conductive layer on the second region.

### CROSS-REFERENCE TO RELATED APPLICATION

This application claims priority from Korean Patent Application No. 10-2014-0106987 filed on Aug. 18, 2014 in the Korean Intellectual Property Office, and all the benefits accruing therefrom under 35 U.S.C. 119, the contents of which in its entirety are herein incorporated by reference.

### BACKGROUND

1. Technical Field

The present inventive concepts relate to a semiconductor device and a method for fabricating the same.

2. Description of the Related Art

To adjust a threshold voltage of a semiconductor chip, a thickness of a gate conductive layer may be varied. However, in consideration of manufacturability and stability of semiconductor chip, there may be a limitation in decreasing or increasing the thickness of the gate conductive layer. Therefore, a method for adjusting the threshold voltage while maintaining the thickness of the gate conductive layer is required. To achieve a stable operation of a semiconductor chip, it is also required to improve a threshold voltage distribution for providing relatively uniform threshold voltages from the semiconductor chip.

### SUMMARY

According to an aspect of the present inventive concept, there is provided a method for fabricating a semiconductor device, the method including forming a gate insulation layer on a substrate including a first region and a second region, forming a first gate conductive layer and a capping layer on the first region and the second region and then heat-treating the substrate, removing the capping layer from the first region and the second region, forming a second gate conductive layer on the first region and the second region, nitriding the second gate conductive layer, and forming a third gate conductive layer on the second region.

In some embodiments, the step of removing the capping layer from the first region and the second region further comprises removing the first gate conductive layer from the first region and the second region.

In some embodiments, the step of forming the gate insulation layer on the substrate comprises: forming an interface layer on the substrate; and forming a high-k gate insulation layer on the interface layer, wherein the second gate conductive layer direct contacts the high-k gate insulation layer.

In some embodiments, the step of forming the gate insulation layer on the substrate comprises: forming a first trench and a second trench on the first region and the second region, respectively; and forming the gate insulation layer along lateral surfaces and bottom surfaces of the first trench and the second trench.

In some embodiments, the forming of the third gate conductive layer on the second region comprises: forming the third gate conductive layer on the second gate conductive layer of the first region and the second region; forming a mask pattern on the second region; and removing the second gate conductive layer from the first region using the mask pattern.

In some embodiments, the step of nitriding the second gate conductive layer is performed using a gas including ammonia (NH₃) or plasma-state ammonia (NH₃).

In some embodiments, the step of nitriding the second gate conductive layer using the gas including ammonia (NH₃) is performed at a temperature ranging from about 500° C. to about 700° C.

In some embodiments, the step of nitriding the second gate conductive layer using the plasma-state ammonia (NH₃) is performed at a temperature ranging from about 25° C. to about 400° C.

In some embodiments, the second gate conductive layer comprises a TaN layer.

According to another aspect of the present inventive concept, there is provided a method for fabricating a semiconductor device, the method including forming a gate insulation layer on a substrate including a first region and a second region, forming a first gate conductive layer and a capping layer on the first region and the second region and then heat-treating the substrate, removing the first gate conductive layer and the capping layer from the first region and the second region, forming a second gate conductive layer on the first region and the second region, forming a third gate conductive layer on the second region, and nitriding the second gate conductive layer of the first region.

In some embodiments, the step of nitriding the second gate conductive layer of the first region comprises implanting a gas including ammonia (NH₃) into the second gate conductive layer of the first region and third gate conductive layer of the second region.

In some embodiments, the second gate conductive layer of the first region is exposed to the gas including ammonia (NH₃) and the second gate conductive layer of the second region is not exposed to the gas including ammonia (NH₃).

In some embodiments, after forming the second gate conductive layer on the first region and the second region, further comprising nitriding the second gate conductive layer.

According to still another aspect of the present inventive concept, there is provided a method for fabricating a semiconductor device, the method including forming a first fin type active pattern and a second fin type active pattern on a substrate, forming a first trench crossing the first fin type active pattern on the first fin type active pattern and forming a second trench crossing the second fin type active pattern on the second fin type active pattern, forming a first TaN layer along lateral surfaces and a bottom surface of the first trench and forming a second TaN layer along lateral surfaces and a bottom surface of the second trench, implanting a nitride gas on the first TaN layer and the second TaN layer, forming a TiN layer on the second TaN layer, and implanting a nitride gas on the first TaN layer and the TiN layer.

In some embodiments, the nitride gas includes ammonia (NH₃).

According to a further aspect of the present inventive concept, there is provided a semiconductor device including an interlayer insulation layer formed on a substrate and including a first trench and a second trench, a first gate insulation layer formed along lateral surfaces and a bottom surface of the first trench and a second gate insulation layer formed along lateral surfaces and a bottom surface of the second trench, a first TaN layer formed on the first gate insulation layer and nitrided, a second TaN layer formed on the second gate insulation layer and nitrided, and a TiN layer formed on the second TaN layer and nitrided.

In some embodiments, the semiconductor device further comprises: a first TiN layer formed between the first gate insulation layer and the first TaN layer; and a second TiN layer formed between the second gate insulation layer and the second TaN layer.

In some embodiments, the TiN layer is formed on the second TaN layer and is not formed on the first TaN layer.

In some embodiments, the first trench is formed in an NMOS region and the second trench is formed in a PMOS region.

In some embodiments, the first TaN layer, the second TaN layer or the TiN layer is nitrided using a gas including ammonia (NH₃) or plasma-state ammonia (NH₃).

### BRIEF DESCRIPTION OF THE DRAWINGS

The above and other features and advantages of the present inventive concept will become more apparent by describing in detail preferred embodiments thereof with reference to the attached drawings in which:

FIGS. 1 to 7 illustrate a method of fabricating a semiconductor device according to an embodiment of the present inventive concept;

FIGS. 8 to 11 illustrate a method of fabricating a semiconductor device according to another embodiment of the present inventive concept;

FIGS. 12 to 14 illustrate a method of fabricating a semiconductor device according to another embodiment of the present inventive concept;

FIGS. 15 to 18 illustrate a method of fabricating a semiconductor device according to still another embodiment of the present inventive concept;

FIG. 19 is a schematic block diagram illustrating a memory card including semiconductor devices fabricated according to some embodiments of the present inventive concept;

FIG. 20 is a schematic block diagram illustrating an information processing system using a semiconductor device fabricated by semiconductor device fabricating methods according to some embodiments of the present inventive concept; and

FIG. 21 is a block diagram of an electronic device including a semiconductor device fabricated by a semiconductor device fabricating method according to some embodiments of the present inventive concept.

### DETAILED DESCRIPTION OF EMBODIMENTS

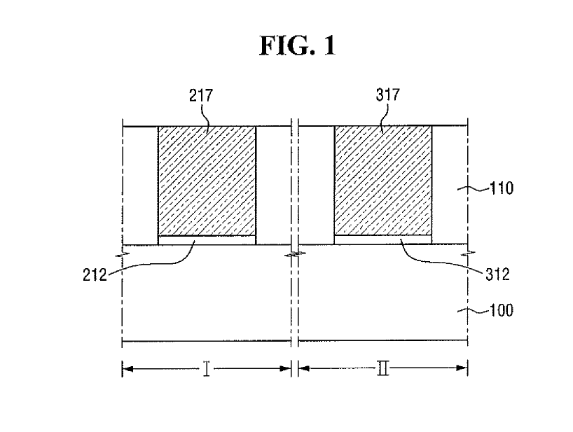

FIGS. 1 to 7 illustrate a method of fabricating a semiconductor device according to an embodiment of the present inventive concept.

Referring to FIG. 1, a substrate 100 may include a first region I and a second region II. The first region I and the second region II may be connected to each other or may be spaced apart from each other. In some embodiments of the present inventive concept, the first region I may be an NMOS region and the second region II may be a PMOS region.

The substrate 100 may be bulk silicon or a silicon-on-insulator (SOI). Alternatively, the substrate 100 may be a silicon substrate, or a substrate made of other materials selected from the group consisting of, for example, germanium, silicon germanium, indium antimonide, lead telluride compound, indium arsenide, indium phosphide, gallium arsenide, and gallium antimonide, but aspects of the present inventive concept are not limited thereto.

A first dummy gate dielectric layer 212 and a first dummy gate 217 are formed on the first region I of the substrate 100. A second dummy gate dielectric layer 312 and a second dummy gate 317 are formed on the second region II of the substrate 100.

Each of the first dummy gate dielectric layer 212 and the second dummy gate dielectric layer 312 may include, for example, one of silicon oxide (SiO₂), silicon oxynitride (SiON) and a combination thereof. The first dummy gate dielectric layer 212 and the second dummy gate dielectric layer 312 may be formed by, for example, thermal treatment, chemical treatment, atomic layer deposition (ALD) or chemical vapor deposition (CVD).

The first dummy gate dielectric layer 212 and the second dummy gate dielectric layer 312 may include, for example, silicon (Si), specifically, poly Si, amorphous silicon (a-Si) and a combination thereof. The first dummy gate 217 and the second dummy gate 317 may both not be doped with impurity or may be doped with similar impurities. Alternatively, one of the first dummy gate 217 and the second dummy gate 317 may be doped and the other may not be doped. Alternatively, one of the first dummy gate 217 and the second dummy gate 317 may be doped with an n type material (e.g., arsenic, phosphorus, or the like) and the other may be doped with a p type material (e.g., boron, or the like).

After the first dummy gate 217 and the second dummy gate 317 are formed, source/drain regions are formed at opposite sides of the first dummy gate 217 and the second dummy gate 317.

An interlayer insulation layer 110 covering the first dummy gate 217 and the second dummy gate 317 is formed on the substrate 100. The interlayer insulation layer 110 may include, for example, at least one of a low k material, oxide, nitride and oxynitride. Examples of the low k material may include flowable oxide (FOX), tonen silazene (TOSZ), undoped silica glass (USG), borosilica glass (BSG), phosphosilaca glass (PSG), borophosphosilica glass (BPSG), plasma enhanced tetra ethyl ortho silicate (PRTEOS), fluoride silicate glass (FSG), high density plasma (HDP), plasma enhanced oxide (PEOX), flowable CVD (FCVD), and combinations thereof, but aspects of the present inventive concept are not limited thereto.

The interlayer insulation layer 110 is planarized to expose top surfaces of the first dummy gate 217 and the second dummy gate 317. For example, the planarizing may be performed by chemical mechanical polishing (CMP).

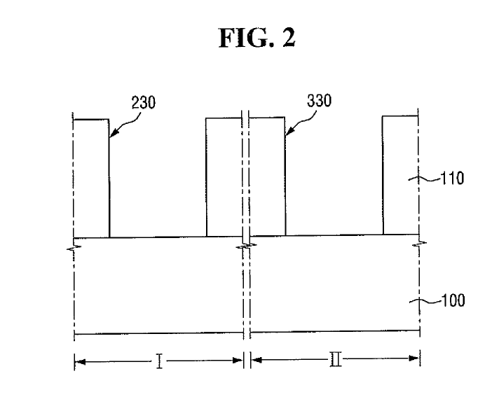

Referring to FIG. 2, the first dummy gate 217 and the second dummy gate 317 are removed. After the first dummy gate 217 and the second dummy gate 317 are removed, the first dummy gate dielectric layer 212 and the second dummy gate dielectric layer 312 are removed, thereby forming a first trench 230 and a second trench 330. A top surface of the substrate 100 may be exposed by the first trench 230 and the second trench 330.

In other words, the interlayer insulation layer 110 including the first trench 230 and the second trench 330 is formed on the substrate 100. The first trench 230 is formed on the first region I and the second trench 330 is formed on the second region II. In some embodiments of the present inventive concept, the first trench 230 is formed on the NMOS region and the second trench 330 is formed on the PMOS region.

The first dummy gate 217, the second dummy gate 317, the first dummy gate dielectric layer 212 and the second dummy gate dielectric layer 312 may be removed by wet etching or dry etching.

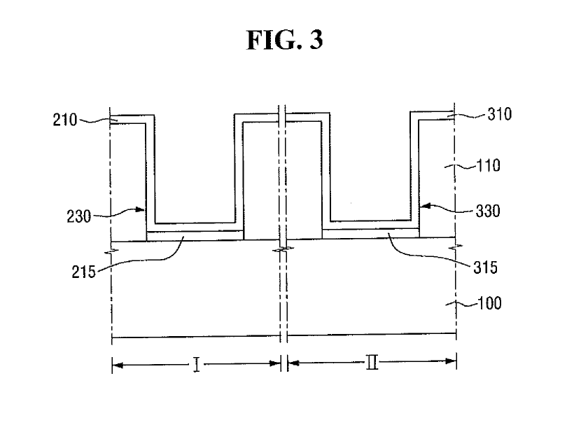

Referring to FIG. 3, a gate insulation layer is formed on the substrate 100. First, a first interface layer 215 and a second interface layer 315 are formed on a bottom surface of the first trench 230 and a bottom surface of the second trench 330, respectively.

The first interface layer 215 and the second interface layer 315 may include silicon oxide. The first interface layer 215 and the second interface layer 315 may be formed using, for example, chemical oxidation, UV oxidation, or dual plasma oxidation.

A high-k gate insulation layer 210 is conformally formed on the top surface of the interlayer insulation layer 110 and on the sidewall surfaces and bottom surface of the first trench 230. In addition, along with the high-k gate insulation layer 210, a high-k gate insulation layer 310 is conformally formed on the top surface of the interlayer insulation layer 110 and on the sidewall surfaces and bottom surface of the second trench 330. In detail, the high-k gate insulation layers 210 and 310 are formed on the first interface layer 215 and the second interface layer 315, respectively.

In some embodiments of the present inventive concept, the high-k gate insulation layers 210 and 310 may be simultaneously formed using, for example, CVD or ALD. The high-k gate insulation layers 210 and 310 may include, for example, one or more selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but not limited thereto.

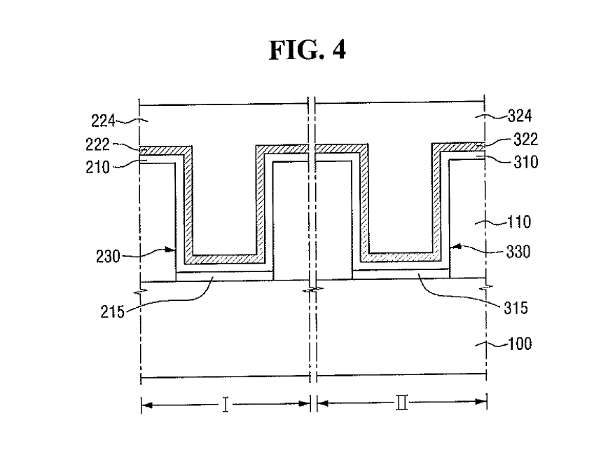

Referring to FIG. 4, first gate conductive layers 222 and 322 are formed on the high-k gate insulation layers 210 and 310, respectively.

The first gate conductive layers 222 and 322 may be conformally formed along the high-k gate insulation layers 210 and 310 using, for example, CVD or ALD. In some embodiments of the present inventive concept, the first gate conductive layers 222 and 322 may be simultaneously formed and may include, for example, a TiN layer.

Capping layers 224 and 324 are formed on the first gate conductive layers 222 and 322, respectively. Thereafter, the capping layers 224 and 324 may be subjected to heat treatment. The capping layers 224 and 324 may include, for example, one of amorphous silicon (a-Si), poly silicon (poly Si), and a combination thereof. When the heat treatment is performed, the capping layers 224 and 324 may prevent thicknesses of the first interface layer 215 and the second interface layer 315 from increasing.

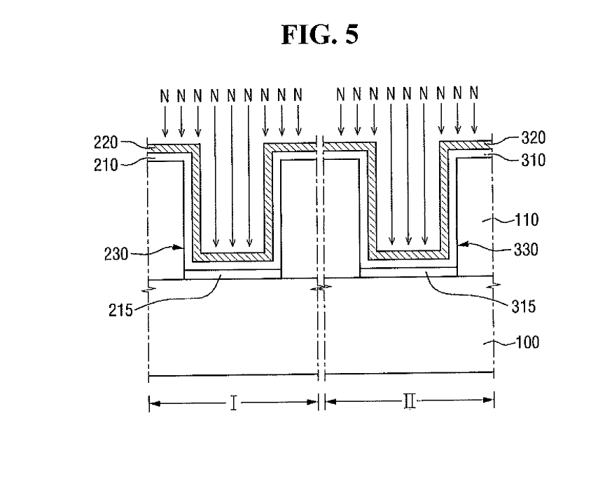

Referring to FIG. 5, the first gate conductive layers 222 and 322 formed on the high-k gate insulation layers 210 and 310 and the capping layers 224 and 324 are removed, thereby exposing the high-k gate insulation layers 210 and 310. A second gate conductive layer 220 is formed along lateral surfaces and a bottom surface of the first trench 230 and a second gate conductive layer 320 is formed along lateral surfaces and a bottom surface of the second trench 330. In this case, the second gate conductive layers 220 and 320 may be brought into direct contact with the high-k gate insulation layers 210 and 310.

The second gate conductive layers 220 and 320 may be conformally formed along the high-k gate insulation layers 210 and 310 using, for example, CVD or ALD. In some embodiments of the present inventive concept, the second gate conductive layers 220 and 320 may be simultaneously formed and may include, for example, a TaN layer.

Next, the second gate conductive layers 220 and 320 may be nitrided. In some embodiments of the present inventive concept, the step of nitriding the second gate conductive layers 220 and 320 may be performed using a gas including ammonia (NH₃). For example, the second gate conductive layers 220 and 320 may be nitrided using the gas including ammonia (NH₃) at a temperature ranging from 500° C. to 700° C. In some embodiments of the present inventive concept, the step of nitriding the second gate conductive layers 220 and 320 may be performed using plasma-state ammonia (NH₃). For example, the second gate conductive layers 220 and 320 may be nitrided using the plasma-state ammonia (NH₃) at a temperature ranging from 25° C. to 400° C. However, various embodiments of the present inventive concept do not limit the method of performing the nitriding to those listed herein.

In various embodiments of the present inventive concept, a threshold voltage of the NMOS region can be effectively adjusted by nitriding the second gate conductive layers 220 and 320. In an embodiment, the semiconductor device fabricating method may include additionally forming a TiN layer to adjust the threshold voltage of the NMOS region. However, if the TiN layer is additionally formed in the NMOS region, the threshold voltage of the NMOS region may be increased, so that a desired threshold voltage may not be attained. In this case, the effect of increasing the threshold voltage of the NMOS region, which occurs when the TiN layer is additionally formed, may be suppressed by nitriding the TaN layers formed after the forming of the TiN layer, that is, the second gate conductive layers 220 and 320, according to various embodiments of the present inventive concept. Accordingly, the threshold voltage of the semiconductor device may be adjusted while maintaining the second gate conductive layers 220 and 320 in thickness ranges enabling mass production of semiconductor devices. Meanwhile, the second gate conductive layers 220 and 320 may be oxidized during the semiconductor device manufacturing process, resulting in non-uniformity in the threshold voltage distribution. In this case, in various embodiments of the present inventive concept, the second gate conductive layers 220 and 320 oxidized by nitriding the same may be reduced, thereby providing a uniform threshold voltage distribution of the semiconductor device.

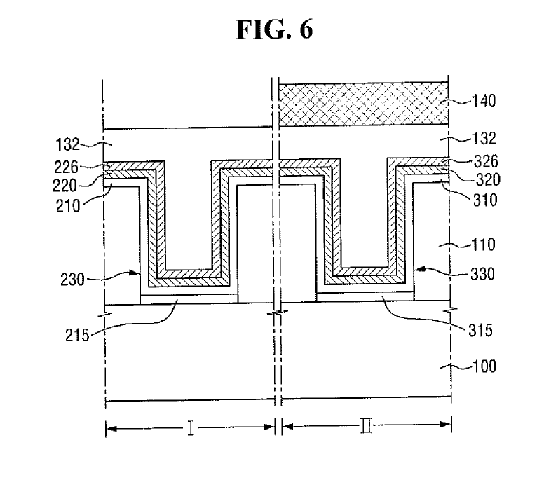

Referring to FIG. 6, first, third gate conductive layers 226 and 326 may be formed on the second gate conductive layers 220 and 320. The third gate conductive layers 226 and 326 may be conformally formed along the second gate conductive layers 220 and 320 using, for example, CVD or ALD. In some embodiments of the present inventive concept, the third gate conductive layers 226 and 326 may be simultaneously formed and may include, for example, a TiN layer.

A mask layer 132 filling the first trench 230 and the second trench 330 is formed on the third gate conductive layers 226 and 326. The mask layer 132 may include a good gap-filling capability to efficiently fill the first trench 230 and the second trench 330.

Next, a photoresist pattern 140 is formed on the mask layer 132. The photoresist pattern 140 exposes the mask layer 132 formed on the third gate conductive layer 226 while covering the mask layer 132 formed on the third gate conductive layer 326. That is to say, the photoresist pattern 140 covers the second region II and exposes the first region I. In addition, the photoresist pattern 140 may overlap with the third gate conductive layer 326 but may not overlap with the third gate conductive layer 226.

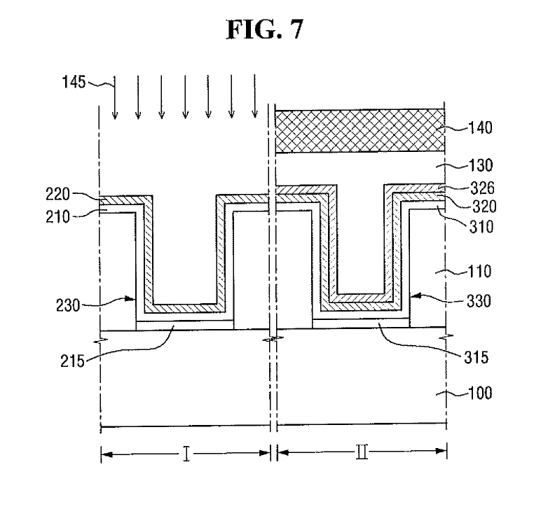

Referring to FIG. 7, the mask layer 132 filling the first trench 230 is removed using the photoresist pattern 140 as a mask in an etching process 145. Through the etching process 145, a mask pattern 130 is formed on the third gate conductive layer 326. The mask pattern 130 fills the second trench 330.

In other words, the mask layer 132 formed on the third gate conductive layer 226 is removed from the first region I by the etching process 145, thereby forming the mask pattern 130. The mask pattern 130 and the photoresist pattern 140 formed on the third gate conductive layer 326 may have a stacked structure to be used as an etch mask in a subsequent process.

In an embodiment, the removing of the mask layer 132 from the first region I may further include removing the third gate conductive layer 226 from the first region I. As the mask layer 132 and the third gate conductive layer 226 are removed from the first region I, the second gate conductive layer 220 is exposed in the first region I. Here, the second gate conductive layer 320 of the second region II is covered by the mask pattern 130 and the photoresist pattern 140.

The mask layer 132 filling the first trench 230 and the third gate conductive layer 226 may be removed by dry etching. The dry etching may be, for example, a reactive ion etching (RIE). As an example of the dry etching for forming the mask pattern 130, the mask layer 132 filling the first trench 230 is etched using a mixed gas including oxygen as an etching gas to then be removed. The mixed gas used as the etching gas may include chlorine in addition to oxygen. The mixed gas may further include helium. As another example of the dry etching for forming the mask pattern 130, the mask layer 132 filling the first trench 230 is etched using a mixed gas including nitrogen and hydrogen as an etching gas to then be removed.

Thereafter, processes of forming gate metals on the first region I and the second region II are performed. In detail, For example, after the mask layer 132 is removed from the first region I, the second gate conductive layer 220 is removed using the mask pattern 130 as a mask to expose the high-k gate insulation layer 210 in the first region I. Here, the second gate conductive layer 220 may be removed by wet etching using an etching solution including, for example, hydrogen peroxide (H₂O₂). Next, the photoresist pattern 140 and the mask pattern 130 formed on the second region II are removed to expose the second gate conductive layer 320 in the second region II. The photoresist pattern 140 and the mask pattern 130 may be removed by, for example, a gas including hydrogen (H₂) and nitrogen (N₂). Then, a first metal gate may be formed to fill the first trench 230 and a second metal gate may be formed to fill the second trench 330. Accordingly, for example, an n type transistor may be formed on the first region I and a p type transistor may be formed on the second region II.

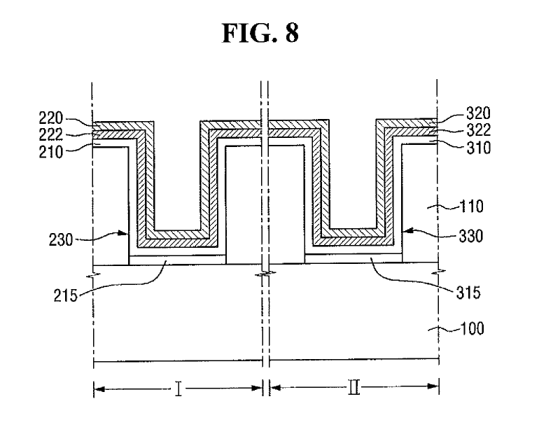

FIGS. 8 to 11 illustrate intermediate process steps in a method of fabricating a semiconductor device according to another embodiment of the present inventive concept.

The following description will focus on differences between the present embodiment and the previous embodiment shown in FIGS. 1 to 7.

Referring to FIGS. 5 and 8, the present embodiment is different from the previous embodiment in that capping layers 224 and 324 are formed on first gate conductive layers 222 and 322, respectively, followed by performing heat treatment, and only the capping layers 224 and 324 are removed without removing the first gate conductive layers 222 and 322. Accordingly, the high-k gate insulation layers 210 and 310 are not exposed while the first gate conductive layers 222 and 322 are exposed. Next, the second gate conductive layer 220 is formed along lateral surfaces and a bottom surface of the first trench 230 and the second gate conductive layer 320 is formed along lateral surfaces and a bottom surface of the second trench 330.

As described above, in some embodiments of the present inventive concept, the first gate conductive layers 222 and 322 may be simultaneously formed and may include, for example, a TiN layer. In some embodiments of the present inventive concept, the second gate conductive layers 220 and 320 may be simultaneously formed and may include, for example, a TaN layer.

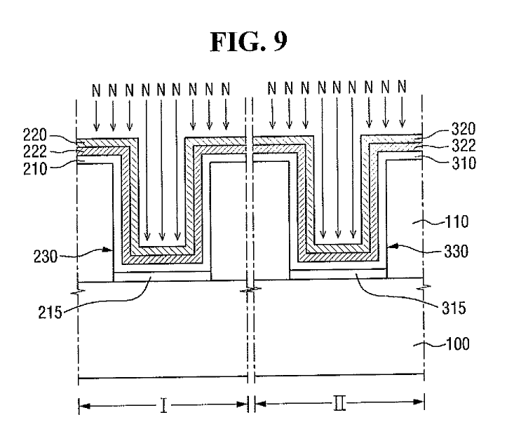

Referring to FIG. 9, next, the second gate conductive layers 220 and 320 may be nitrided. As described above, in some embodiments of the present inventive concept, the nitriding of the second gate conductive layers 220 and 320 may be performed using a gas including ammonia (NH₃). For example, the second gate conductive layers 220 and 320 may be nitrided using the gas including ammonia (NH₃) at a temperature ranging from 500° C. to 700° C. In some embodiments of the present inventive concept, the step of nitriding the second gate conductive layers 220 and 320 may be performed using plasma-state ammonia (NH₃). For example, the second gate conductive layers 220 and 320 may be nitrided using the plasma-state ammonia (NH₃) at a temperature ranging from 25° C. to 400° C. However, various embodiments of the present inventive concept do not limit the nitriding method to those illustrated herein.

In various embodiments of the present inventive concept, a threshold voltage of the NMOS region can be effectively adjusted by nitriding the second gate conductive layers 220 and 320. In an embodiment, a TiN layer may be additionally formed to adjust the threshold voltage of the NMOS region in the semiconductor device manufacturing process. The TiN layer additionally formed in the NMOS region may lead to an increase in the threshold voltage of the NMOS region, making it difficult to attain a desired threshold voltage. According to various embodiments of the present inventive concept, the effect of increasing the threshold voltage of the NMOS region can be suppressed by nitriding TaN layers subsequently formed after the forming of the TiN layer, that is, the second gate conductive layers 220 and 320. Accordingly, the threshold voltage of the semiconductor device can be adjusted while maintaining the second gate conductive layers 220 and 320 in thicknesses ranges enabling mass production of semiconductor devices. The second gate conductive layers 220 and 320 may be oxidized during the semiconductor device manufacturing process, resulting in non-uniformity in the threshold voltage distribution. In various embodiments of the present inventive concept, the oxidized second gate conductive layers 220 and 320 resulting from the nitriding of the second gate conductive layers 220 and 320 may be reduced, thereby providing a uniform threshold voltage distribution of the semiconductor device.

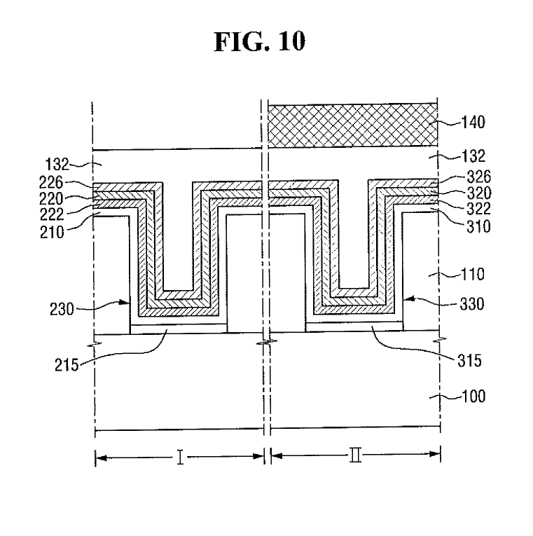

Referring to FIG. 10, first, the third gate conductive layers 226 and 326 may be formed on the first gate conductive layers 222 and 322. Next, the mask layer 132 filling the first trench 230 and the second trench 330 is formed on the third gate conductive layers 226 and 326. Next, the photoresist pattern 140 covering the second region II while exposing the first region I is formed on the mask layer 132.

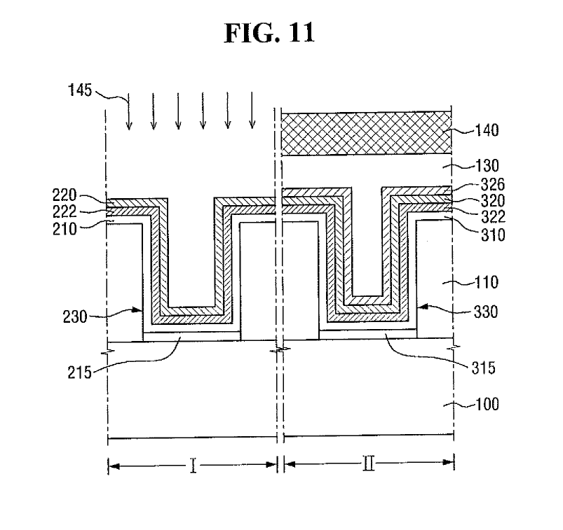

Referring to FIG. 11, the mask layer 132 filling the first trench 230 is removed using the photoresist pattern 140 as a mask in an etching process 145. Through the etching process 145, a mask pattern 130 is formed on the second gate conductive layer 320. The mask pattern 130 fills the second trench 330. Meanwhile, the removing of the mask layer 132 from the first region I may further include removing the third gate conductive layer 226 of the first region I. As the result of the removing the mask layer 132 and the third gate conductive layer 226 from the first region I, the second gate conductive layer 220 is exposed in the first region I. However, the second gate conductive layer 320 of the second region II may be covered by the mask pattern 130 and the photoresist pattern 140.

Processes of forming metal gates on the first region I and the second region II are performed. For example, after the mask layer 132 is removed from the first region I, the second gate conductive layer 220 is removed using the mask pattern 130 as a mask, thereby exposing the first gate conductive layer 222 in the first region I. Meanwhile, the first gate conductive layer 222 is further removed from the first region I, thereby exposing the high-k gate insulation layer 210 in the first region I. Here, the first gate conductive layer 222 or the second gate conductive layer 220 may be removed by wet etching using an etching solution including, for example, hydrogen peroxide (H₂O₂). Next, the photoresist pattern 140 and the mask pattern 130 formed on the second region II are removed, thereby exposing the second gate conductive layer 320 in the second region II. The photoresist pattern 140 and the mask pattern 13Q may be removed using a gas including, for example, hydrogen (H₂) and nitrogen (N₂). Thereafter, a first metal gate may be formed to fill the first trench 230 and a second metal gate may be formed to fill the second trench 330. Accordingly, For example, an n type transistor may be formed on the first region I and a p type transistor may be formed on the second region II.

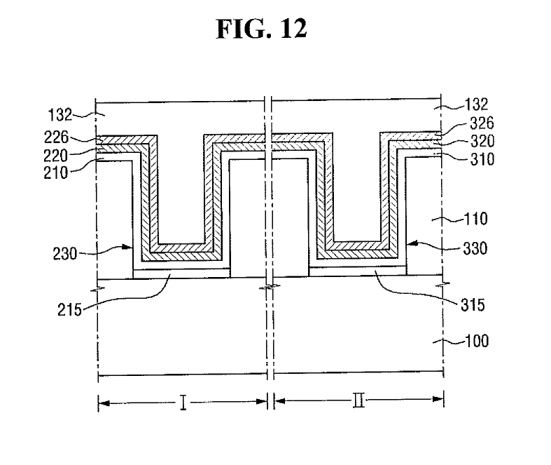

FIGS. 12 to 14 illustrate a method of fabricating a semiconductor device according to another embodiment of the present inventive concept.

Referring to FIGS. 5, 12 and 13, second gate conductive layers 220 and 320 are not nitrified after the second gate conductive layers 220 and 320 are formed on high-k gate insulation layers 210 and 310. In an embodiment, the first gate conductive layers 222 and 322 and the capping layers 224 and 324 are removed, thereby exposing the high-k gate insulation layers 210 and 310. Next, the second gate conductive layer 220 is formed along lateral surfaces and a bottom surface of the first trench 230 and the second gate conductive layer 320 is formed along lateral surfaces and a bottom surface of the second trench 330. Thereafter, third gate conductive layers 226 and 228 are formed on the second gate conductive layers 220 and 320 without nitriding the second gate conductive layers 220 and 320, and a mask layer 132 filling the first trench 230 and the second trench 330 is then formed.

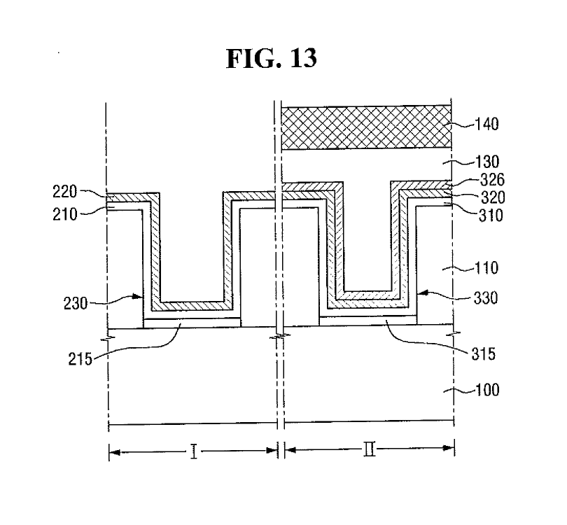

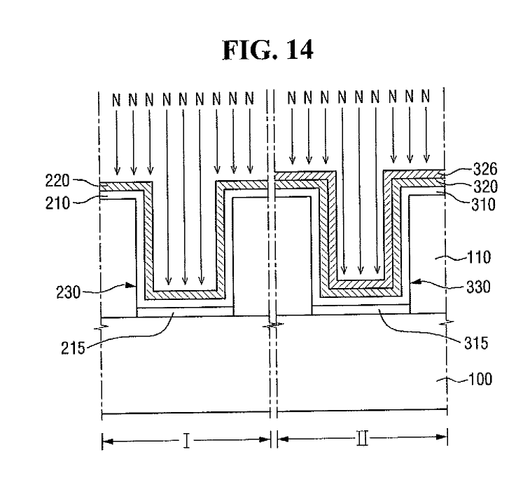

Referring to FIGS. 13 and 14, the mask layer 132 filling the first trench 230 is removed using a photoresist pattern 140 as a mask of an etching process 145 and the mask pattern 130 is formed on the third gate conductive layer 326 through the etching process 145, followed by nitriding the second gate conductive layer 220 and the third gate conductive layer 326. In detail, after the photoresist pattern 140 and the mask pattern 130 formed on the second region II are removed, a gas for nitriding, for example, a gas including ammonia (NH₃), may be implanted on the second gate conductive layer 220 of the first region I and the third gate conductive layer 326 of the second region II.

Here, the second gate conductive layer 220 of the first region I is exposed to the gas including ammonia (NH₃) while the third gate conductive layer 326 of the second region II is not exposed to the gas including ammonia (NH₃).

In various embodiments of the present inventive concept, as the result of nitriding the second gate conductive layers 220 and 320, as described above with reference to FIGS. 5 and 9, a threshold voltage of the NMOS region can be effectively adjusted. Accordingly, the threshold voltage of the semiconductor device can be adjusted while maintaining the second gate conductive layers 220 and 320 in thicknesses ranges enabling mass production of semiconductor devices. Meanwhile, the second gate conductive layers 220 and 320 may be oxidized during the semiconductor device manufacturing process, resulting in non-uniformity in the threshold voltage distribution. In this case, in various embodiments of the present inventive concept, the second gate conductive layers 220 and 320 oxidized by nitriding the same may be reduced, thereby providing a uniform threshold voltage distribution of the semiconductor device.

Meanwhile, in the method for fabricating a semiconductor device according to still another embodiment of the present inventive concept, two nitriding processes may be performed. That is to say, after forming the second gate conductive layers 220 and 320, as shown in FIG. 5, the second gate conductive layers 220 and 320 are firstly nitrided, followed by performing the etching process 145, as shown in FIG. 14, to form a third gate conductive layer 326 on the second gate conductive layer 320, and the second gate conductive layer 220 and the third gate conductive layer 326 are then secondly nitrided.

Accordingly, after the second gate conductive layers 220 and 320 are nitrided, the second gate conductive layer 220 is nitrided once more to reduce the oxidized second gate conductive layers 220 and 320, thereby more effectively providing a uniform threshold voltage distribution of the semiconductor device.

The semiconductor device manufactured according to the present embodiment include an interlayer insulation layer 110 formed on a substrate 100 and including a first trench 230 and a second trench 330, a first gate insulation layer formed along lateral surfaces and bottom surfaces of the first trench 230, a second gate insulation layer formed along lateral surfaces and bottom surfaces of the second trench 330, a first TaN layer formed on the first gate insulation layer and nitrided, and a second TaN layer formed on the second gate insulation layer and nitrided. A nitride TiN layer may further be formed on the second TaN layer. For example, when each of the second TaN layer and the TiN layer formed on the second TaN layer is nitrided once, two nitriding processes may be performed on the first TaN layer. Here, the first gate insulation layer may include a first interface layer 215 and a high-k gate insulation layer 210, and the second gate insulation layer may include a second interface layer 315 and a high-k gate insulation layer 310. Meanwhile, the first TaN layer may be the second gate conductive layer 220 and the second TaN layer may be the second gate conductive layer 320.

According to some embodiments of the present inventive concept, the semiconductor device may further include a first TiN layer formed between the first gate insulation layer and the first TaN layer and a second TiN layer formed between the second gate insulation layer and the second TaN layer. Meanwhile, according to some embodiments of the present inventive concept, the TiN layer may be formed on the second TaN layer while not being formed on the first TaN layer. As described above, the nitriding of the first TaN layer, the second TaN layer or the TiN layer may be performed using a gas including ammonia (NH₃) or plasma-state ammonia (NH₃).

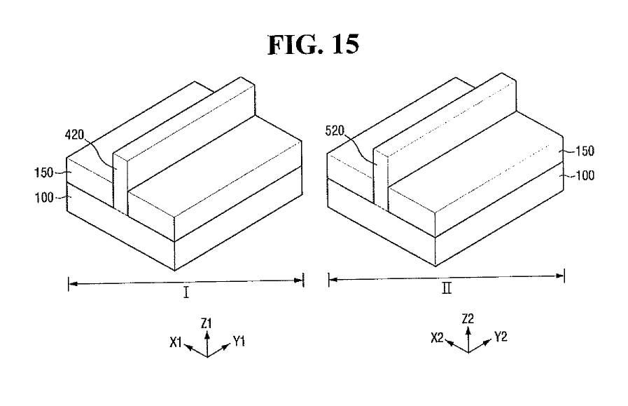

Hereinafter, a method of fabricating a semiconductor device according to still another embodiment of the present inventive concept will be described with reference to FIGS. 15 to 18.

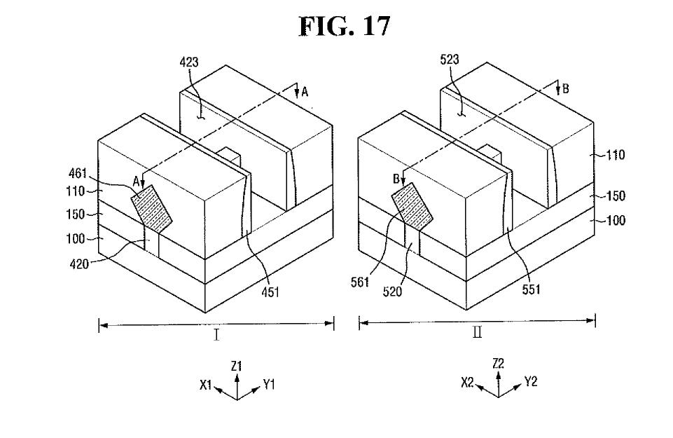

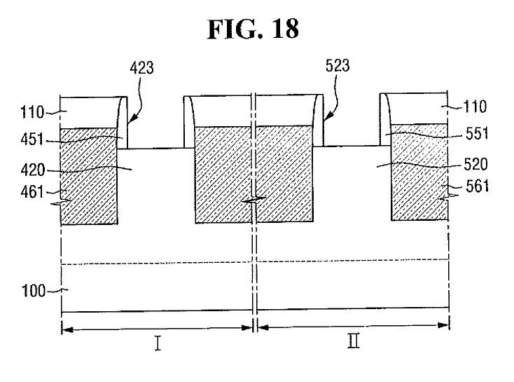

FIGS. 15 to 18 illustrate a method of fabricating a semiconductor device according to still another embodiment of the present inventive concept. Specifically, FIG. 18 illustrates cross-sectional views taken along lines A-A and B-B of FIG. 17.

Referring to FIG. 15, a first fin type active pattern 420 and a second fin type active pattern 520 are formed on the substrate 100. In some embodiments of the present inventive concept, the first fin type active pattern 420 is formed on the first region I and the second fin type active pattern 520 is formed on the second region II.

The first fin type active pattern 420 and the second fin type active pattern 520 may extend lengthwise along second directions Y1 and Y2, respectively. The first fin type active pattern 420 and the second fin type active pattern 520 may be portions of the substrate 100 and may include epitaxial layers grown from the substrate 100. An isolation layer 150 may cover lateral surfaces of the first fin type active pattern 420 and the second fin type active pattern 520.

The first fin type active pattern 420 and the second fin type active pattern 520 may include, for example, an element semiconductor material, such as silicon or germanium. In an embodiment, the first fin type active pattern 420 and the second fin type active pattern 520 may include compound semiconductors, for example, Group IV-IV compound semiconductors or Group III-V compound semiconductors. In detail, examples of the Group IV-IV compound semiconductors doped into the first fin type active pattern 420 and the second fin type active pattern 520 may include a binary compound or a ternary compound including at least two elements selected from the group consisting of carbon (C), silicon (Si), germanium (Ge), and tin (Sn), and compounds doped with Group IV elements. The III-V group compound semiconductor doped into the first fin type active pattern 420 and the second fin type active pattern 520 may include, for example, a binary compound, a ternary compound or a quaternary compound, prepared by combining at least one group III element of aluminum (Al), gallium (Ga) and indium (In) with at least one group V element of phosphorus (P), arsenic (As) and antimony (Sb).

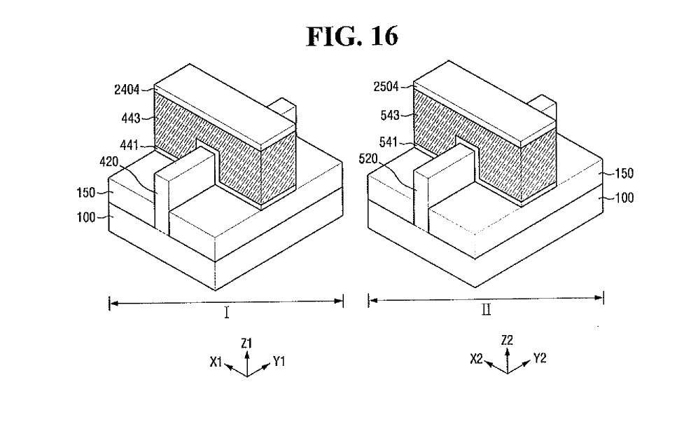

Referring to FIG. 16, an etching process is performed using a first hard mask pattern 2404 and a second hard mask pattern 2504, thereby forming a third dummy gate 443 crossing the first fin type active pattern 420 and extending in a first direction X1 and a fourth dummy gate 543 crossing the second fin type active pattern 520 and extending in a first direction X2. Here, a third dummy gate insulation layer 441 may be formed between the first fin type active pattern 420 and the third dummy gate 443 and a fourth dummy gate insulation layer 541 may be formed between the second fin type active pattern 520 and the fourth dummy gate 543.

The third dummy gate insulation layer 441 and the fourth dummy gate insulation layer 541 may include, for example, at least one of silicon oxide (SiO₂), silicon oxynitride (SiON) and a combination thereof. The third dummy gate 443 and the fourth dummy gate 543 may include, for example, at least one of polysilicon (poly Si), amorphous silicon (a-Si) and a combination thereof.

Referring to FIGS. 16 to 18, the third dummy gate 443 and the third dummy gate insulation layer 441 are removed, thereby forming a third trench 423 crossing the first fin type active pattern 420 on the first fin type active pattern 420. In addition, the fourth dummy gate 543 and the fourth dummy gate insulation layer 541 are removed, thereby forming a Fourth trench 523 crossing the second fin type active pattern 520 on the second fin type active pattern 520.

In an embodiment, a first spacer 451 and a second spacer 551 are formed on sidewalls of the third dummy gate 443 and the fourth dummy gate 543, respectively. When the first spacer 451 and the second spacer 551 are formed, portions of the first fin type active pattern 420 and the second fin type active pattern 520 not overlapping with the third dummy gate 443 and the fourth dummy gate 543 are removed, thereby forming recesses.

A first source/drain 461 and a second source/drain 561 are formed at opposite sides of the third dummy gate 443 and the fourth dummy gate 543, respectively.

An interlayer insulation layer 110 covering the first source/drain 461 and the second source/drain 561 is formed. Through a planarizing process, top surfaces of the third dummy gate 443 and the fourth dummy gate 543 are exposed.

The third dummy gate 443 and the third dummy gate insulation layer 441 are removed, thereby forming the third trench 423 on the first region I and the fourth dummy gate 543 and the fourth dummy gate insulation layer 541 are removed, thereby forming the fourth trench 523 on the second region II.

Subsequent processes after the forming of the third trench 423 and the fourth trench 523, as shown in FIG. 18, are substantially the same as those of the previous embodiments, and detailed descriptions thereof will not be given or will be briefly given.

In some embodiments of the present inventive concept, a first TaN layer is formed along lateral surfaces and a bottom surface of the third trench 423 of the first region I and a second TaN layer is formed along lateral surfaces and a bottom surface of the fourth trench 523. As described above, gate conductive layers previously formed along the lateral surfaces and a bottom surface of the third trench 423 and the fourth trench 523 may have been removed before the forming of the first TaN layer and the second TaN layer. Next, after a nitrogen gas is implanted on the first TaN layer and the second TaN layer, a TiN layer may be formed on the second TaN layer.

In some embodiments of the present inventive concept, As described above, the gate conductive layers including, for example, TiN, previously been formed along the lateral surfaces and the bottom surface of the third trench 423 and the fourth trench 523, may not have been removed before the forming of the first TaN layer and the second TaN layer. That is to say, on the gate conductive layer including TiN, the first TaN layer is formed along the lateral surfaces and the bottom surface of the third trench 423 of the first region I and the second TaN layer is formed along the lateral surfaces and the bottom surface of the fourth trench 523. Next, the nitride gas is implanted on the first TaN layer and the second TaN layer, thereby forming a TiN layer on the second TaN layer.

Meanwhile, in some embodiments of the present inventive concept, the first TaN layer is formed along the lateral surfaces and the bottom surface of the third trench 423 of the first region I, and the second TaN layer is formed along the lateral surfaces and the bottom surface of the fourth trench 523. Next, the TiN layer may be formed on the second TaN layer without implanting a nitride gas into the first TaN layer and the second TaN layer. Then, a nitride gas may be implanted on the first TaN layer and the TiN layer.

In some embodiments of the present inventive concept, the first TaN layer is formed along the lateral surfaces and the bottom surface of the third trench 423 of the first region I, and the second TaN layer is formed along the lateral surfaces and the bottom surface of the fourth trench 523. Next, the nitride gas may be implanted on the first TaN layer and the second TaN layer and a TiN layer may be formed on the second TaN layer. Next, the nitride gas may be implanted on the first TaN layer and the TiN layer. That is to say, the nitride gas may be implanted two times during the semiconductor device manufacturing process.

In some embodiments of the present inventive concept, the nitride gas may include ammonia (NH₃).

As described above, as the result of the nitriding of the first TaN layer and the second TaN layer, a threshold voltage of the NMOS region can be effectively reduced, thereby suppressing the effect of increasing the threshold voltage of the NMOS region, occurring due to, for example, additionally forming of a TiN layer. Accordingly, the threshold voltage of the semiconductor device may be adjusted while maintaining the TaN layer in a thickness range enabling mass production of semiconductor devices. Meanwhile, the TaN layer may be oxidized during the semiconductor device manufacturing process, resulting in non-uniformity in the threshold voltage distribution. In this case, in various embodiments of the present inventive concept, the TaN layer oxidized by nitriding the same may be reduced, thereby providing uniformity in the threshold voltage distribution of the semiconductor device.

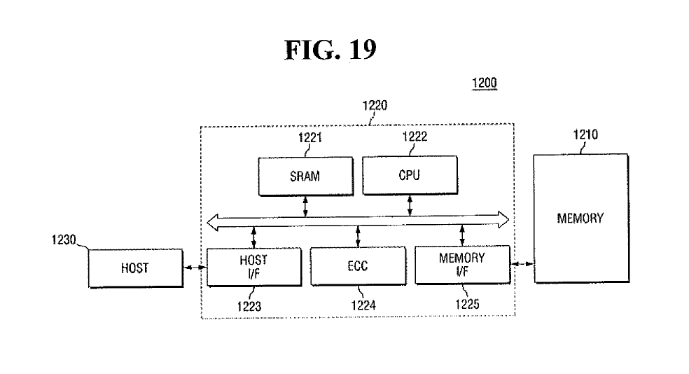

FIG. 19 is a schematic block diagram illustrating a memory card including semiconductor devices fabricated according to some embodiments of the present inventive concept.

Referring to FIG. 19, a memory 1210 fabricated according to some embodiments of the present inventive concept may be employed to a memory card 1200. The memory card 1200 fabricated according to some embodiments of the present inventive concept includes a memory controller 1220 controlling data exchange between a host and the memory 1210. The SRAM 1221 is used as a working memory of a central processing unit 1222. A host interface 1223 includes a data exchange protocol of the host connected to the memory card 1200. An error correction block 1224 detects and corrects an error included in data read from the memory 1210. The memory interface 1225 interfaces with the memory 1210 according to the present inventive concept. The central processing unit 1222 performs an overall controlling operation for data exchange of the memory controller 1220.

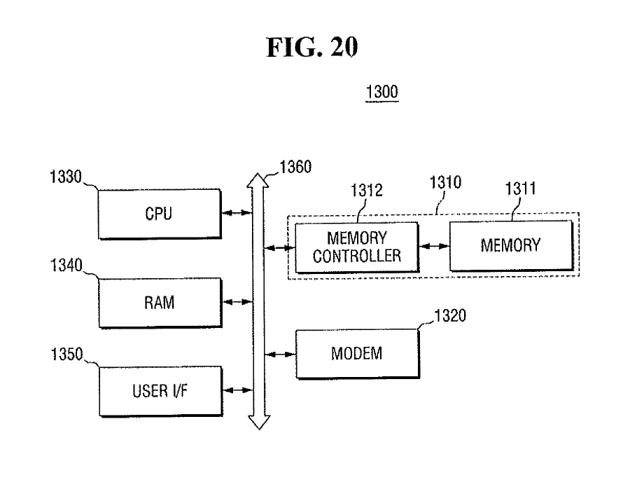

FIG. 20 is a schematic block diagram illustrating an information processing system using a semiconductor device fabricated by semiconductor device fabricating methods according to some embodiments of the present inventive concept.

Referring to FIG. 20, an information processing system 1300 may include a memory system 1310 including semiconductor devices fabricated by semiconductor device fabricating methods according to embodiments of the present inventive concept. The information processing system 1300 in accordance with the present inventive concept includes the memory system 1310 and a modem 1320, a central processing unit (CPU) 1330, a random access memory (RAM) 1340, and a user interface 1350 that are electrically connected to a system bus 1360, respectively. The memory system 1310 may include a memory 1311 and a memory controller 1312 and may have a configuration that is the same as or substantially similar to the memory card 1200 shown in FIG. 19. The memory system 1310 may store data processed by the central processing unit 1330 or data received from an external device. The information processing system 1300 can be applied to a memory card, a solid-state drive (SSD), a camera image sensor or other various kinds of chip sets. For example, the memory system 1310 may be configured to employ an SSD. In this case, the information processing system 1300 may process store huge amounts of data in a stable, reliable manner.

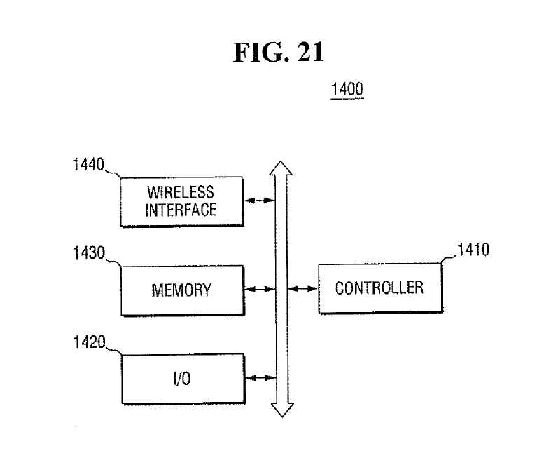

FIG. 21 is a block diagram of an electronic device including a semiconductor device fabricated by a semiconductor device fabricating method according to some embodiments of the present inventive concept.

Referring to FIG. 21, the electronic device 1400 may include a semiconductor device according to various embodiments of the present inventive concept. The electronic device 1400 may be applied to a wireless communication device (for example, a personal digital assistant (PDA), a notebook computer, a portable computer, a web tablet, a wireless phone, and/or a wireless digital music player) or any type of electronic device capable of transmitting and/or receiving information in a wireless environment.

The electronic device 1400 may include a controller 1410, an input/output device (I/O) 1420, a memory 1430, and a wireless interface 1440. Here, the memory 1430 may include a semiconductor device according to various embodiments of the present inventive concept. The controller 1410 may include a microprocessor, a digital signal processor, and a processor capable of performing functions similar to these components. The memory 1430 may be used to store commands processed by the controller 1410 (or user data). The wireless interface 1440 may be used to exchange data through a wireless data network. The wireless interface 1440 may include an antenna or a wired/wireless transceiver. For example, the electronic device 1400 may use a third generation communication system protocol, such as CDMA, GSM, NADC, E-TDMA, WCDMA, CDMA2000, or the like.

Meanwhile, the semiconductor device to which the present inventive concept can be applied may include a multi-gate field electric transistor (MuGFET), for example, a fin type field electric transistor (FinFET).

In addition, the semiconductor device to which the present inventive concept can be applied may include a logic region and an SRAM region. The transistor formed according to the aforementioned embodiment may be selectively formed as a logic nFET, a logic pFET, an SRAM nFET, or an SRAM pFET in the logic region or the SRAM region. Meanwhile, the regions to which the present inventive concept can be applied are not limited to the logic region and the SRAM region. Rather, the present inventive concept may also be applied to a region other than the logic region, for example, a memory region where a memory, such as DRAM, MRAM, RRAM, PRAM, etc. is formed.

The present inventive concept provides a method for fabricating a semiconductor device, which can adjust a threshold voltage of the semiconductor device while maintaining the thickness of a gate conductive layer.

The present inventive concept also provides a semiconductor device, which can adjust a threshold voltage of the semiconductor device while maintaining the thickness of a gate conductive layer.

The present inventive concept also provides a method for fabricating a semiconductor device, which can provide a uniform threshold voltage distribution.

The present inventive concept also provides a semiconductor device, which can provide a uniform threshold voltage distribution.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

1. A method for fabricating a semiconductor device, the method comprising:
forming a gate insulation layer on a substrate including a first region and a second region;
forming a first gate conductive layer and a capping layer on the first region and the second region and heat-treating the substrate;
removing the capping layer from the first region and the second region;
forming a second gate conductive layer on the first region and the second region;
nitriding the second gate conductive layer; and
forming a third gate conductive layer on the second region.

2. The method of claim 1, wherein the step of removing the capping layer from the first region and the second region further comprises removing the first gate conductive layer from the first region and the second region.

3. The method of claim 2, wherein the step of forming the gate insulation layer on the substrate comprises:
forming an interface layer on the substrate; and
forming a high-k gate insulation layer on the interface layer,
wherein the second gate conductive layer direct contacts the high-k gate insulation layer.

4. The method of claim 1, wherein the step of forming the gate insulation layer on the substrate comprises:
forming a first trench and a second trench on the first region and the second region, respectively; and
forming the gate insulation layer along lateral surfaces and bottom surfaces of the first trench and the second trench.

5. The method of claim 4, wherein the forming of the third gate conductive layer on the second region comprises:
forming the third gate conductive layer on the second gate conductive layer of the first region and the second region;
forming a mask pattern on the second region; and
removing the second gate conductive layer from the first region using the mask pattern.

6. The method of claim 1, wherein the step of nitriding the second gate conductive layer is performed using a gas including ammonia (NH₃) or plasma-state ammonia (NH₃).

7. The method of claim 6, wherein the step of nitriding the second gate conductive layer using the gas including ammonia (NH₃) is performed at a temperature ranging from about 500° C. to about 700° C.

8. The method of claim 6, wherein the step of nitriding the second gate conductive layer using the plasma-state ammonia (NH₃) is performed at a temperature ranging from about 25° C. to about 400° C.

9. The method of claim 1, wherein the second gate conductive layer comprises a TaN layer.

10. A method for fabricating a semiconductor device, the method comprising:
forming a gate insulation layer on a substrate including a first region and a second region;
forming a first gate conductive layer and a capping layer on the first region and the second region and heat-treating the substrate;
removing the first gate conductive layer and the capping layer from the first region and the second region;
forming a second gate conductive layer on the first region and the second region;
forming a third gate conductive layer on the second region; and
nitriding the second gate conductive layer of the first region.

11. The method of claim 10, wherein the step of nitriding the second gate conductive layer of the first region comprises implanting a gas including ammonia (NH₃) into the second gate conductive layer of the first region and third gate conductive layer of the second region.

12. The method of claim 11, wherein the second gate conductive layer of the first region is exposed to the gas including ammonia (NH₃) and the second gate conductive layer of the second region is not exposed to the gas including ammonia (NH₃).

13. The method of claim 10, after forming the second gate conductive layer on the first region and the second region, further comprising nitriding the second gate conductive layer.

14. A method for fabricating a semiconductor device, the method comprising:
forming a first fin type active pattern and a second fin type active pattern on a substrate;
forming a first trench crossing the first fin type active pattern on the first fin type active pattern and forming a second trench crossing the second fin type active pattern on the second fin type active pattern;
forming a first TaN layer along lateral surfaces and a bottom surface of the first trench and forming a second TaN layer along lateral surfaces and a bottom surface of the second trench;
implanting a nitride gas on the first TaN layer and the second TaN layer;
forming a TiN layer on the second TaN layer; and
implanting a nitride gas on the first TaN layer and the TiN layer.

15. The method of claim 14, wherein the nitride gas includes ammonia (NH₃).

16-20. (canceled)
